(19) United States
(12) Patent Application Publication
(10) Pub. No.: US 2009/0026445 A1
(43) Pub. Date: Jan. 29, 2009

(54) Organic thin film transistor array panel and method for manufacturing the same

(75) Inventors: Jung-Hun Noh, Yongin-si (KR); Keun-Kyu Song, Yongin-si (KR); Seung-Hwan Cho, Hwaseong-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 12/148,908

(22) Filed: Apr. 22, 2008

(30) Foreign Application Priority Data
Jul. 24, 2007 (KR) 10-2007-0074016

(51) Int. Cl. H01L 51/00; H01L 21/00; G02F 1/136

(52) U.S. Cl. 257/40; 438/151; 349/46; 257/E21.409

(57) ABSTRACT

A method for manufacturing an organic thin film transistor array panel includes forming a data line including a source electrode and a drain electrode apart from the data line on a substrate and forming a bank insulating layer including a first opening and a second opening on the data line and the drain electrode. An organic semiconductor is formed in the first opening, sequential deposition is performed of an insulating material layer and a metal layer on the bank insulating layer and the organic semiconductor. A first passivation layer is formed on the metal layer which is etched using the first passivation layer as an etch mask to form a gate line including a gate electrode. The insulating material layer is etched using the first passivation layer as an etch mask to form a gate insulating layer. A second passivation layer is formed on the first passivation layer and a pixel electrode is formed on the second passivation layer.

### CROSS-REFERENCE TO RELATED APPLICATION

This application claims priority to and the benefit of Korean Patent Application No. 10-2007-0074016 filed in the Korean Intellectual Property Office on Jul. 24, 2007, the entire contents of which are incorporated herein by reference.

### BACKGROUND OF THE INVENTION

(a) Field of the Invention

The present invention relates to an organic thin film transistor array panel and a method for manufacturing the same.

(b) Description of the Related Art

Generally, a flat panel display such as a liquid crystal display (LCD), an organic light emitting diode (OLED) display, and an electrophoretic display includes a pair of electric-field generating electrodes and an electro-optical active layer disposed therebetween. A LCD includes a liquid crystal layer as the electro-optical active layer, and an OLED display includes an organic light emitting layer as the electro-optical active layer.

One of the pair of field generating electrodes is usually coupled with a switching element to receive electrical signals, and the electro-optical active layer converts the electrical signals into optical signals to display images.

The switching element for a flat panel display includes a thin film transistor (TFT) having three terminals. Gate lines transmit control signals for controlling the TFTs and data lines transmit data signals to be supplied to the pixel electrodes through the TFTs.

Among the types of TFTs, organic thin film transistors (OTFT) are being actively developed. An OTFT includes an organic semiconductor instead of an inorganic semiconductor such as Si.

An OTFT panel having OTFTs in a matrix alignment includes many differences in structure and manufacturing method in comparison with a panel utilizing conventional TFTs.

One difference is that an OTFT uses a fluorine organic material as an insulating material to improve the characteristics of the organic semiconductor.

However, a lifting phenomenon of the fluorine organic material may be generated upon reaction with a stripper of the photoresist used in the photolithographic processes used in the manufacture of organic thin film transistors. Accordingly it is desirable to eliminate the lifting phenomenon of the organic material due to the reaction with the stripper of the photoresist and to improve the characteristics of the organic semiconductor by using a fluorine organic material as an insulating material.

The above information disclosed in this Background section is only for enhancement of understanding of the background of the invention and therefore it may contain information that does not form the prior art that is already known in this country to a person of ordinary skill in the art.

### SUMMARY OF THE INVENTION

An organic thin film transistor array panel according to an exemplary embodiment of the present invention includes a substrate, a source electrode formed on the substrate, a drain electrode spaced apart from the source electrode, a bank insulating layer formed on the source electrode and the drain electrode and having a first opening exposing portions of the source electrode and the drain electrode and a second opening exposing a portion of the drain electrode, an organic semiconductor disposed in the first opening and contacting the source electrode and the drain electrode, a gate insulating layer formed on the organic semiconductor, a gate line formed on the gate insulating layer and including a gate electrode, a first passivation layer formed on the gate line and having the same shape as the gate line, and a pixel electrode formed on the first passivation layer and connected to the drain electrode through the second opening.

The organic thin film transistor array panel further may include a data line formed on the substrate and connected to the source electrode.

The data line may include a first conductive layer including a transparent conductive oxide, and a second conductive layer including a metal.

The source electrode and the drain electrode may be made of the transparent conductive oxide.

The transparent conductive oxide may include ITO or IZO.

The organic thin film transistor array panel further includes a second passivation layer formed on the bank insulating layer and the first passivation layer.

The second passivation layer may include a third opening connected to the second opening.

The bank insulating layer may be made of an acryl-based photosensitive resin including a compound containing fluorine.

The compound containing fluorine may include at least one selected from a fluoro-surfactant, fluoro-nanoparticles, and fluoropolymer nanobeads.

The first passivation layer may include an acryl-based organic material.

A method for manufacturing an organic thin film transistor array panel according to an exemplary embodiment of the present invention includes forming a data line including a source electrode and a drain electrode apart from the data line on a substrate, forming a bank insulating layer including a first opening and a second opening on the data line and the drain electrode, forming an organic semiconductor in the first opening, sequentially depositing an insulating material layer and a metal layer on the bank insulating layer and the organic semiconductor, forming a first passivation layer on the metal layer, etching the metal layer using the first passivation layer as an etch mask to form a gate line including a gate electrode, etching the insulating material layer using the first passivation layer as an etch mask to form a gate insulating layer, and forming a pixel electrode on the first passivation layer.

The forming of the data line and the drain electrode may include sequentially depositing a first conductive layer including a transparent conductive oxide and a second conductive layer including a metal, forming a first photoresist member and a second photoresist member that is thinner than the first photoresist member on the second conductive layer, sequentially etching the first and second conductive layers using the first and second photoresist members as an etch mask, removing the second photoresist member, and etching the second conductive layer using the first photoresist member as an etch mask.

The second photoresist member may be disposed at a position corresponding to the source electrode and the drain electrode.

The organic semiconductor may be formed using an Inkjet printing method.

The method may further include forming a second passivation layer on the first passivation layer.

The second passivation layer may include a third opening connected to the second opening.

### BRIEF DESCRIPTION OF THE DRAWINGS

FIG. 1 is a layout view of a thin film transistor array panel according to an exemplary embodiment of the present invention;

FIG. 2 is a cross-sectional view of the thin film transistor array panel shown in FIG. 1 taken along the line II-II;

FIG. 8, FIG. 10, and FIG. 15 are layout views of the organic thin film transistor array panel shown in FIGS. 1 and 2 in intermediate steps of a manufacturing method according to an embodiment of the present invention;

FIG. 9 is a cross-sectional view of the organic thin film transistor array panel shown in FIG. 8 taken alone the line IX-IX;

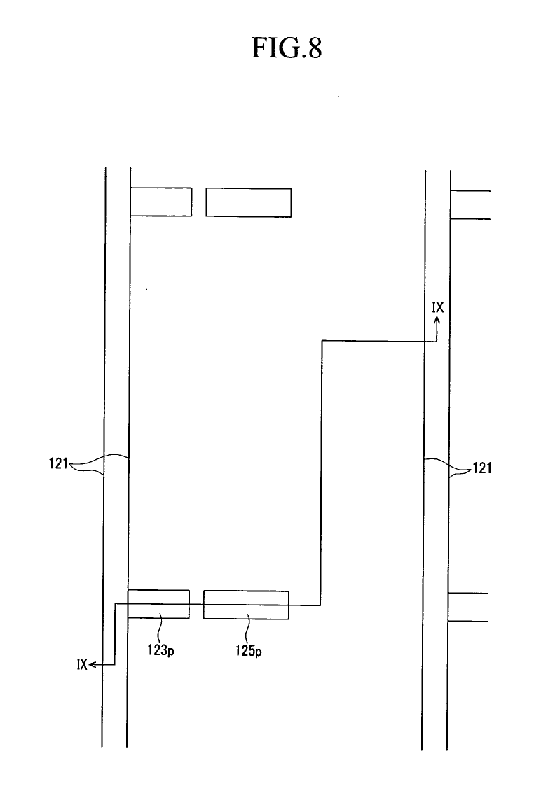

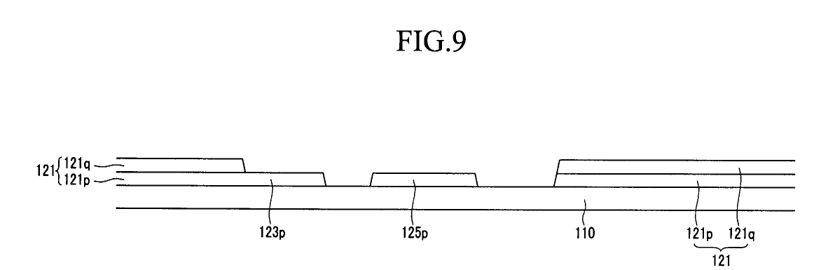

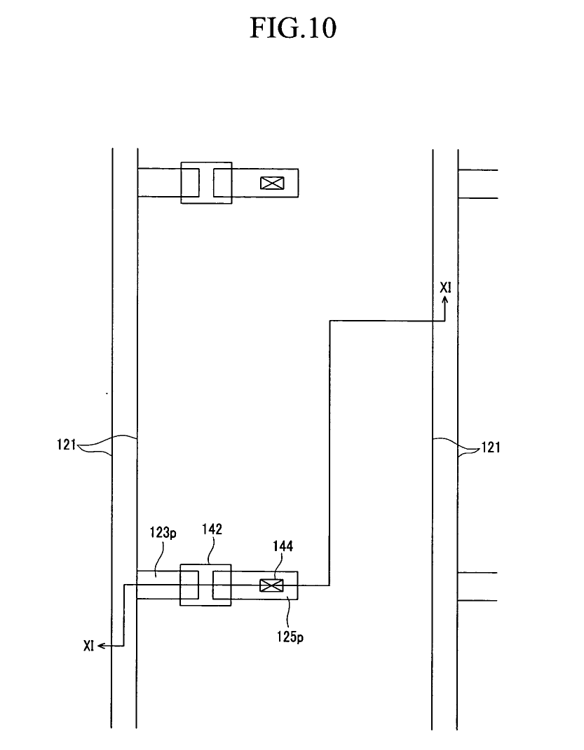

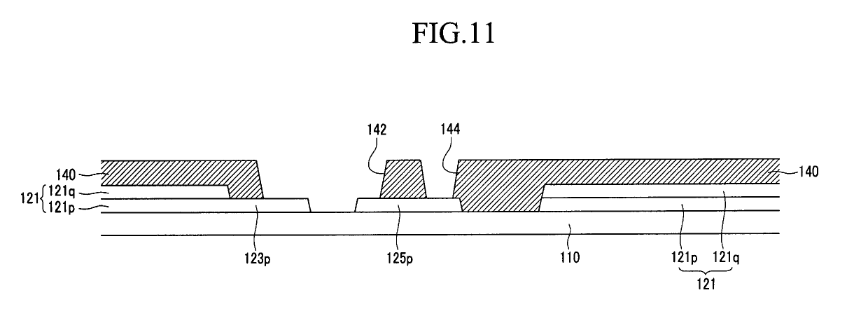

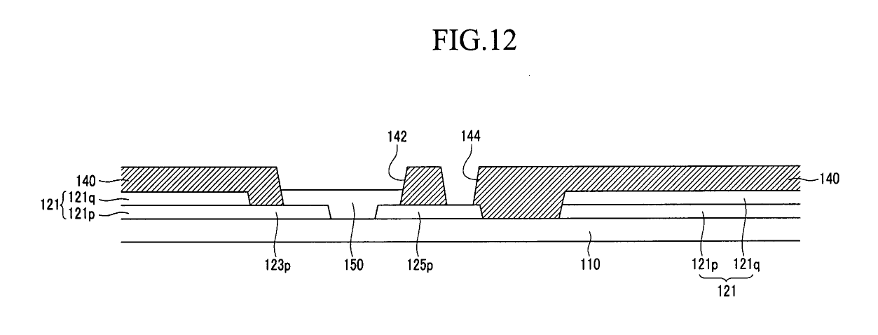

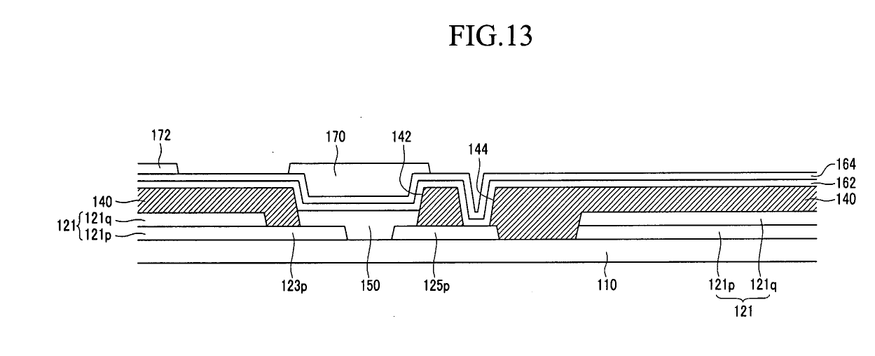

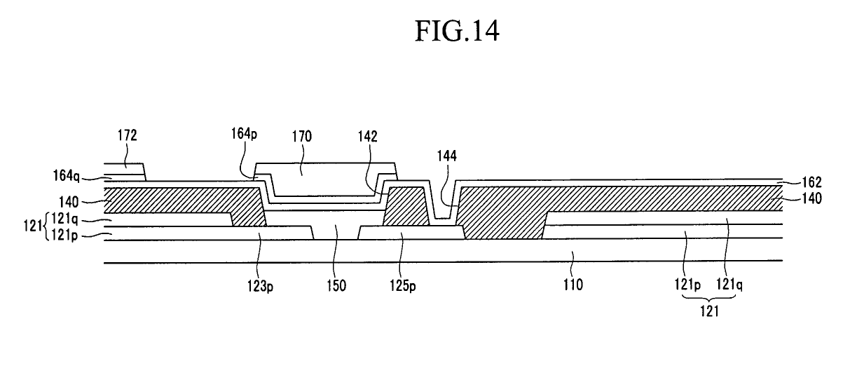

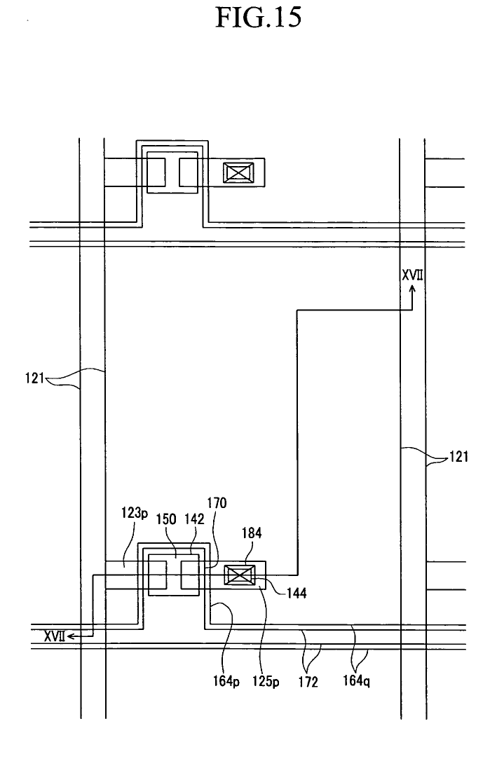

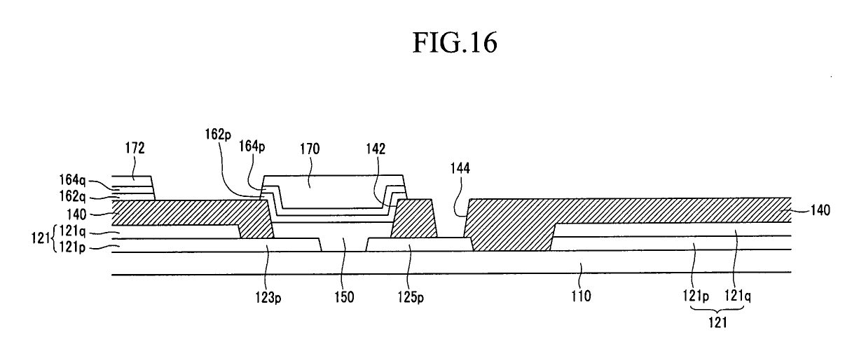

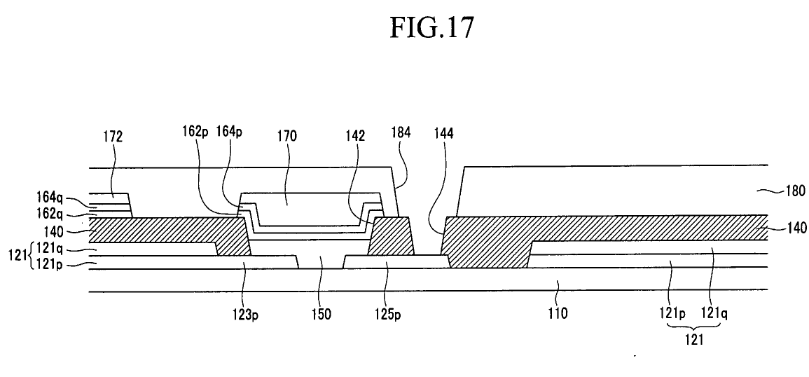

FIGS. 3 to 7 are cross-sectional views of the organic thin film transistor array panel shown in FIGS. 8 and 9 in the previous steps;

FIG. 11 is a cross-sectional view of the organic thin film transistor array panel shown in FIG. 10 taken along the line XI-XI;

FIG. 16 is a cross-sectional view of the organic thin film transistor array panel shown in FIG. 15 taken along the line XVII-XVII;

FIGS. 12 to 14 are cross-sectional views of the organic thin film transistor array panel shown in FIGS. 15 and 16 in the previous steps; and

FIG. 17 is a cross-sectional view of the organic thin film transistor array panel shown in FIG. 16 including a second passivation layer.

### DETAILED DESCRIPTION OF THE EMBODIMENTS

Embodiments of the present invention are described below with reference to the accompanying drawings. As those skilled in the art will realize, the described embodiments may be modified in various different ways, all without departing from the spirit or scope of the present invention.

In the drawings, the thickness of layers, films, panels, and regions are exaggerated for clarity. Like reference numerals designate like elements throughout the specification. When an element such as a layer, film, region, or substrate is referred to as being “on” another element, it can be directly on the other element or intervening elements may also be present. In contrast, when an element is referred to as being “directly on” another element, there are no intervening elements present.

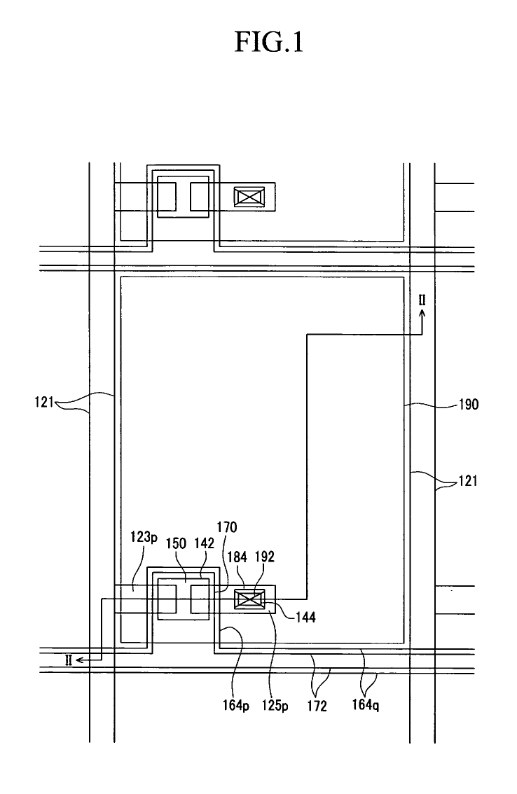

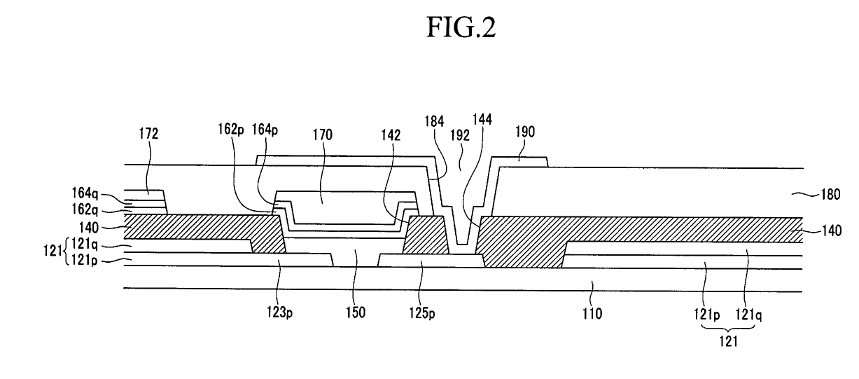

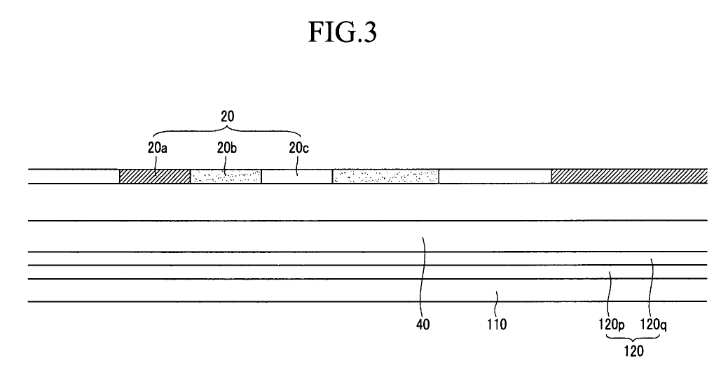

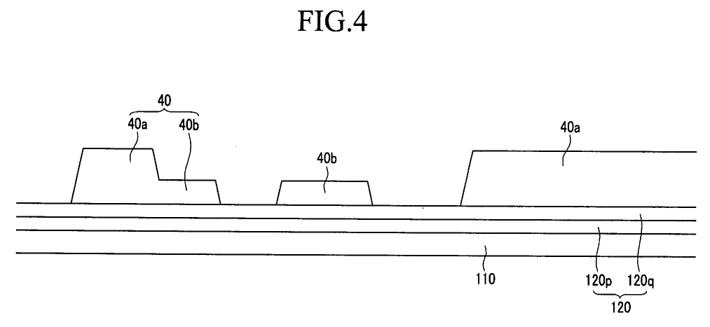

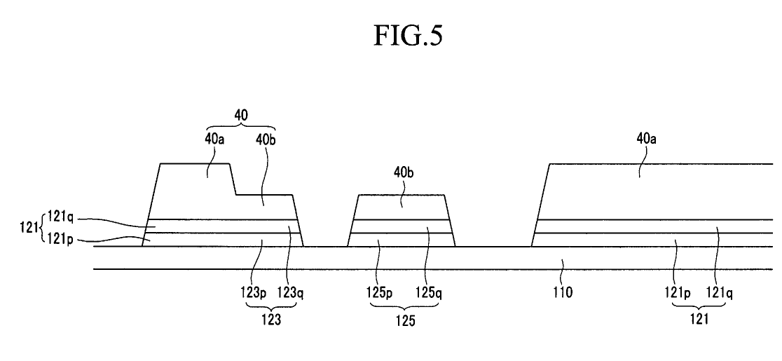

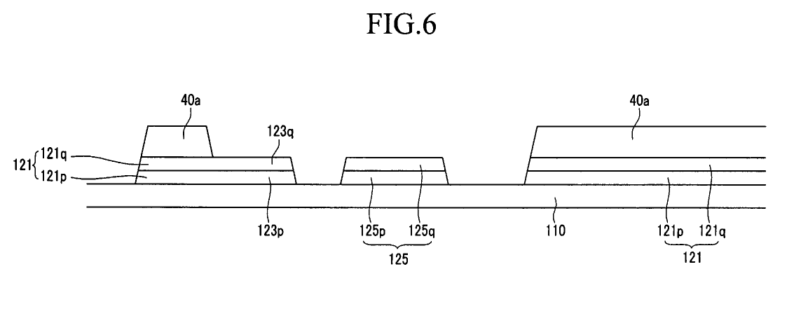

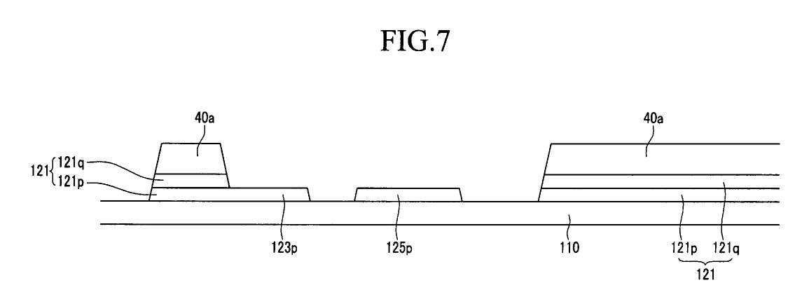

One embodiment of an organic thin film transistor array panel array panel for use in a liquid crystal display according to the present invention is described below with reference to FIGS. 1 and 2.

FIG. 1 is a layout view of a portion of an organic thin film transistor array panel according to an embodiment of the present invention, and FIG. 2 is a sectional view of the organic thin film transistor array panel shown in FIG. 1 taken along the line II-II.

As shown in FIGS. 1 and 2, a plurality of data lines 121 and a plurality of drain electrodes 125p are formed on an insulating substrate 110 made of a material such as transparent glass, silicone, or plastic.

The data lines 121 for transmitting data signals extend substantially in a longitudinal direction. Each data line 121 includes a plurality of projections forming source electrodes 123p protruding aside, and a data pad portion (not shown) for contact with another layer or an external driving circuit.

The data lines 121 are preferably made of double layers including lower data lines 121p and upper data lines 121q.

The lower data lines 123p include the source electrodes 123p and are preferably made of a transparent conductive material such as ITO or IZO

A portion of the upper data lines 121q are removed from the source electrodes 123p. The upper data lines 121q are preferably made of a low resistivity metal such as molybdenum (Mo), a molybdenum alloy (Mo alloy), chromium (Cr), a chromium alloy (Cr alloy), aluminum (Al), an aluminum alloy (Al alloy), copper (Cu), a copper alloy (Cu alloy), silver (Ag), and a silver alloy (Ag alloy). Here, it is preferable that the upper and lower data lines 121p and 121q have different etch rates for high etch selectivity.

The drain electrodes 125p have island shapes and face the source electrodes 123p. The drain electrodes 125p are also preferably made of a transparent conductive material such as ITO and IZO, like the source electrodes 123p.

A bank insulating layer 140 is formed on the data lines 121 and the drain electrodes 125p. Bank insulating layer 140 is preferably made of a photosensitive organic material, and its thickness is in a range of about from about 5000 Å to about 4 μm.

The bank insulating layer 140 includes a plurality of first openings 142 and second openings 144.

The first openings 142 expose portions of the source electrodes 123p and the drain electrodes 125p, and the second openings 144 expose portions of the drain electrodes 125p.

The bank insulating layer 140 may be made of an acryl-based photosensitive resin including a fluorine compound. The fluorine compound may be a fluoro-surfactant, fluoro-nanoparticles, fluoropolymer nanobeads, etc.

It is preferable that the content of the fluorine compound is in a range of from about 1 to about 40 wt % of the total content of the photosensitive organic material. In the case of being included at less than 1 wt %, it is difficult to manifest a surface characteristic, and in the case of being included at more than 40 wt %, since the surface tension is extremely decreased, another layer formed thereon may be non-uniform.

A plurality of organic semiconductors 150 are formed in the first openings 142.

The organic semiconductors 150 contact the source electrodes 123p and the drain electrodes 125p in the first openings 142.

The organic semiconductors 150 may include a high molecular compound or a low molecular compound that is soluble in an aqueous solution or an organic solvent.

The organic semiconductors 150 may be made of or from derivatives of tetracene or pentacene with a substituent. Alternatively, the organic semiconductors 150 may be made of an oligothiophene including four to eight thiophenes connected at positions 2 and 5 of thiophene rings.

The organic semiconductors 150 may be made of polythienylenevinylene, poly3-hexylthiophene, polythiophene, phthalocyanine, or metallized phthalocyanine, or halogenated derivatives thereof. Alternatively, the organic semiconductors 150 may be made of perylene tetracarboxylic dianhydride (PTCDA), naphthalene tetracarboxylic dianhydride (NTCDA), or their imide derivatives. The organic semiconductors 150 may also be made of perylene, coronene, or derivatives thereof with a substituent.

The thickness of the organic semiconductors 150 may be in the range of from about 300 Å to about 1 micron.

A gate insulating layer 162q is formed on the organic semiconductors 150. The gate insulating layer 162q includes a plurality of protrusions 162p protruded upward.

The gate insulating layer 162q is preferably made of or from derivatives of polyacryl, polystyrene, polyimide, polyvinyl alcohol, parylene, perfluorocyclobutane, perfluorovinylether, or benzocyclobutane (BCB).

A plurality of gate lines 164q are formed on the gate insulating layer 162q.

The gate lines 164q for transmitting gate signals extend substantially in a transverse direction and intersect the data lines 121. Each of the gate lines 164q includes a plurality of gate electrodes 164p projecting upward and a gate pad portion (not shown) for contact with another layer or an external driving circuit. The gate electrodes 164p overlap the protrusions 162p of the gate insulating layer 162q via the organic semiconductors 150, and the gate line 164q may have the same shape as the gate insulating layer 162q.

The gate lines 164q are preferably made of a metal having low resistivity such as molybdenum (Mo), a molybdenum alloy (Mo alloy), chromium (Cr), a chromium alloy (Cr alloy), aluminum (Al), an aluminum alloy (Al alloy), copper (Cu), a copper alloy (Cu alloy), silver (Ag), and a silver alloy (Ag alloy).

A first passivation layer 170 and 172 is formed on the gate lines 164q. The first passivation layer 170 and 172 may have the same shape as the gate lines 164q, and is preferably made of an acryl-based organic material.

A second passivation layer 180 is formed on the first passivation layer 170 and 172. The second passivation layer 180 has a plurality of third openings 184 exposing the drain electrodes 125p along with the second openings 144 of the bank insulating layer 140. The second passivation layer 180 protects the organic thin film transistors and the gate lines 164q. The second passivation layer 180 may be formed on a portion or the whole surface of the substrate 110, or optionally may be omitted.

A plurality of pixel electrodes 190 are formed on the second passivation layer 180.

The pixel electrodes 190 are connected to the drain electrode 125p through the second and third openings 144 and 184 of the bank insulating layer 140 and the second passivation layer 180. The pixel electrodes 190 receive data voltages from the organic thin film transistor and generate an electric field in conjunction with a common electrode (not shown) of an opposing display panel (not shown) that is supplied with a common voltage, which convert the electric signal into an optical signal in as electro-optical layer (not shown) disposed between the two electrodes for displaying images.

A method of manufacturing the organic thin film transistor array panel shown in FIGS. 1 and 2 according to an embodiment of the present invention will be described in detail with reference to FIGS. 3-17, as well as FIGS. 1 and 2.

FIG. 8, FIG. 10, and FIG. 15 are layout views of the organic thin film transistor array panel shown in FIGS. 1 and 2 in intermediate steps of a manufacturing method thereof according to an embodiment of the present invention, FIG. 9 is a cross-sectional view of the organic thin film transistor array panel shown in FIG. 8 taken alone the line IX-IX, FIGS. 3 to 7 are cross-sectional views of the organic thin film transistor array panel shown in FIGS. 8 and 9 in the previous steps, FIG. 11 is a cross-sectional view of the organic thin film transistor array panel shown in FIG. 10 taken along the line XI-XI, FIG. 16 is a cross-sectional view of the organic thin film transistor array panel shown in FIG. 15 taken along the line XVII-XVII, FIGS. 12 to 14 are cross-sectional views of the organic thin film transistor array panel shown in FIGS. 15 and 16 in the previous steps, and FIG. 17 is a cross-sectional view of the organic thin film transistor array panel shown in FIG. 16 additionally including a second passivation layer.

Referring to FIG. 3, a first layer 120p made of ITO and a second layer 120q including Mo are sequentially deposited on a substrate 110 by using sputtering, etc to form a conductive layer 120.

Next, a photosensitive film 40 is coated on the second layer 120q, and a mask 20 is disposed for exposure of the photosensitive film 40. Here, the mask 20 includes a semi-transmissive region 20b as well as a shielding region 20a and a transmissive region 20c. The semi-transmissive region 20b has a slit pattern, a lattice pattern, or a thin film(s) with intermediate transmittance or intermediate thickness. When using a slit pattern, it is preferable that the width of the slits or the distance between the slits is smaller than the resolution of a light exposer used for the photolithography.

According to the use of the mask 20, as shown in FIG. 4, the photosensitive film 40 is exposed and developed to form a plurality of first and second portions 40a and 40b having different thickness. The thickness of the second portions 40b is less than that of the first portions 40a. The thickness ratio of the second portions 40b to the first portions 40a is adjusted based on process conditions in subsequent steps, and it is preferable that the thickness of the second portions 40b is equal to or less than about half of the thickness of the first portions 40a.

Next, referring to FIG. 5, the second layer 120q is etched by using the first and second portions 40a and 40b of the photosensitive film 40 as an etch mask to form a plurality of upper data lines 121q and upper drain electrodes 125q. Here, an etchant for etching the MO containing-metal layer may be used such that the first layer 120p made of ITO is not etched due to its high etch selectivity.

Next, the first layer 120p is etched by using the photosensitive film 40 as an etch mask to form a plurality of data lines 121 including preliminary source electrodes 123, and a plurality of preliminary drain electrodes 125. Here, an etchant for etching the ITO layer is used.

Referring to FIG. 6, the second portions 40b of the photoresist film 40 are removed by an etch-back process such as ashing. At the same time, some amount of the exposed portions of the first portions 40a of the photoresist film 40 are removed, thereby decreasing the thickness of the remaining first portions 40a.

Next, portions 123q of the exposed upper data lines 121q and the upper drain electrodes 125q are etched by using the first portions 40a as an etch mask. Here, the etchant for etching the Mo-containing metal layer is used such that the ITO layer having a different etch rate is not etched and exposed.

Next, the first portions 40a are removed.

Accordingly, as shown in FIG. 9, a plurality of data lines 121 having a double-layered structure and a plurality of source electrodes 123p and drain electrodes 125p having signal-layered structures are completed.

Next, referring to FIGS. 10 and 11, an acryl-based photosensitive resin is formed on the whole surface of the substrate 110. An acryl-based photosensitive solution is coated and developed, and is thermally crosslinked at temperature in a range of about 130 to 250° C. to form the photosensitive resin.

Next, the photosensitive resin is patterned to form a bank insulating layer 140 including a plurality of first and second openings 142 and 144.

Here, the acryl-based photosensitive solution includes a compound containing fluorine. The compound containing fluorine may be a fluoro-surfactant, fluoro-nanoparticles, fluoropolymer nanobeads, etc. It is preferable that the content of the compound containing fluorine is in a range of about from 1 to 40 wt % of the total contents of the photosensitive organic material.

Next, as shown in FIG. 12, a plurality of organic semiconductors 150 are formed in the first openings 142. To form the organic semiconductors 150, an organic semiconductor solution is jetted into the first openings 142 using an Inkjet printing method, and a solvent of the organic semi conductor solution is evaporated.

Next, as shown in FIG. 13, an insulating material layer 162 made of a fluorine polymer, a metal layer 164, and a photosensitive organic material layer are sequentially formed on the whole surface of the substrate 110. Then, the photosensitive organic material layer is exposed and developed, and thermally crosslinked to form a first passivation layer 170 and 172.

Next, as shown in FIG. 14, the metal layer 164 is etched by using the first passivation layer 170 and 172 as an etch mask to form a plurality of gate lines 164q including gate electrodes 164p.

Next, referring to FIGS. 15 and 16, the fluorine polymer insulating material layer 162 is etched by using the first passivation layer 170 and 172 as an etch mask to form a plurality of gate insulating layers 162q including protrusions 162p.

Next, as shown in FIG. 17, an organic material is formed on the whole surface of the substrate 110, and patterned with photolithography to form a second passivation layer 180 including a plurality of third openings 184.

Finally, as shown in FIGS. 1 and 2, a plurality of pixel electrodes 190 connected to the drain electrodes 125p through the second openings 144 and the third openings 184 are formed.

As above-described, the photolithography process may be omitted when forming the gate lines 164q and the gate insulating layer 162q in an exemplary embodiment of the present invention. Accordingly, the lifting phenomenon of the bank insulating layer 140 and gate insulating layer 162q due to the photoresist striper for removing the photosensitive film used when forming them may be prevented.

According to an exemplary embodiment of the present invention, the photolithographic step may be omitted when forming the gate lines and the gate insulating layer such that the lifting phenomenon of the bank insulating layer and the gate insulating layer due to the photoresist striper for removing the photosensitive film for forming them may be prevented.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic thin film transistor array panel comprising:
a substrate;
a source electrode formed on the substrate;
a drain electrode spaced apart from the source electrode;
a bank insulating layer formed on the source electrode and the drain electrode, the bank insulating layer having a first opening exposing a portion of the source electrode and a first portion of the drain electrode, the bank insulating layer having a second opening exposing a second portion of the drain electrode;
an organic semiconductor disposed in the first opening and contacting the source electrode and the first portion of the drain electrode;
a gate insulating layer formed on the organic semiconductor;
a gate line formed on the gate insulating layer, the gate line including a gate electrode;
a first passivation layer formed on the gate line and having the same shape as the gate line; and
a pixel electrode formed on the first passivation layer, the pixel electrode connected to the second portion of the drain electrode through the second opening.

2. The organic thin film transistor array panel of claim 1, further comprising
a data line formed on the substrate, the data line being connected to the source electrode.

3. The organic thin film transistor array panel of claim 2, wherein
the data line is comprised of a first conductive layer including a transparent conductive oxide, and a second conductive layer including a metal.

4. The organic thin film transistor array panel of claim 1, wherein
the source electrode and the drain electrode are comprised of a transparent conductive oxide.

5. The organic thin film transistor array panel of claim 3, wherein:
the transparent conductive oxide includes ITO or IZO.

6. The organic thin film transistor array panel of claim 1, further comprising
a second passivation layer formed on at least a portion of the bank insulating layer and the first passivation layer.

7. The organic thin film transistor array panel of claim 6, wherein
the second passivation layer includes a third opening at least a portion of which merges with the second opening.

8. The organic thin film transistor array panel of claim 1, wherein
the bank insulating layer is comprised of an acryl-based photosensitive resin which includes a compound containing fluorine.

9. The organic thin film transistor array panel of claim 8, wherein
the compound containing fluorine includes at least one of a fluoro-surfactant, or fluoro-nanoparticles, or fluoropolymer nanobeads.

10. The organic thin film transistor array panel of claim 1, wherein
the first passivation layer includes an acryl-based organic material.

11. A method for manufacturing an organic thin film transistor array panel comprising:
forming on a substrate a data line including a source electrode and a drain electrode spaced apart from the source electrode;
forming a bank insulating layer including a first opening and a second opening on the data line and the drain electrode;
forming an organic semiconductor in the first opening;
sequentially depositing an insulating material layer and a metal layer on the bank insulating layer and the organic semiconductor;
forming a first passivation layer on the metal layer;
etching the metal layer using the first passivation layer as an etch mask to form a gate line including a gate electrode;
etching the insulating material layer using the first passivation layer as an etch mask to form a gate insulating layer; and
forming a pixel electrode on the first passivation layer.

12. The method of claim 11, wherein
the forming of the data line and the drain electrode comprises:
sequentially depositing a first conductive layer including a transparent conductive oxide and a second conductive layer including a metal;
forming a first photoresist member and a second photoresist member that is thinner than the first photoresist member on the second conductive layer;
sequentially etching the first and second conductive layers using the first and second photoresist members as an etch mask;
removing the second photoresist member; and
etching the second conductive layer using the first photoresist member as an etch mask.

13. The method of claim 12, wherein
the second photoresist member is disposed at a position corresponding to the source electrode and the drain electrode.

14. The method of claim 11, wherein
the organic semiconductor is formed using an Inkjet printing method.

15. The method of claim 11, further comprising
forming a second passivation layer on the first passivation layer.

16. The method of claim 15, wherein
the second passivation layer includes a third opening connected to the second opening.
